(19) United States
(12) Patent Application Publication
(10) Pub. No.: US 2026/0088079 A1
(43) Pub. Date: Mar. 26, 2026

(54) AREA AND POWER EFFICIENT PARTIAL WORD FEATURE IN EMBEDDED MEMORIES

(71) Applicant: STMicroelectronics International N.V., Geneva (CH)

(72) Inventors: Praveen Kumar VERMA, Greater Noida (IN); Sant Swaroop SHRIVASTAVA, AGRA (IN)

(73) Assignee: STMicroelectronics International N.V., Geneva (CH)

(21) Appl. No.: 19/310,591

(22) Filed: Aug. 26, 2025

Related U.S. Application Data
(60) Provisional application No. 63/697,789, filed on Sep. 23, 2024.

(51) Int. Cl. G11C 11/418

(52) U.S. Cl. CPC G11C 11/418

(57) ABSTRACT

A static random-access memory (SRAM) device with enhanced flexibility and power efficiency includes two memory cores with different bit widths and a control section that receives a partial word signal. This signal allows independent control of each memory core, enabling or disabling them selectively. The SRAM device further includes a decoder circuit and multiple word line drivers, which can be independently enabled or disabled for each memory core based on the partial word signal. The word line drivers are organized into two sets, each coupled to the word lines of a respective memory core. Power control circuits selectively provide power to each set of drivers according to the partial word signal. This architecture allows for more granular control over memory access and power consumption, potentially improving the device's overall efficiency and performance in applications requiring variable memory access patterns.

### RELATED APPLICATION

This application claims priority to United States Provisional Application for Patent No. 63/697,789, filed September 23, 2024, the contents of which are incorporated by reference in their entirety.

### TECHNICAL FIELD

This disclosure relates to the field of integrated circuit design, specifically to static random-access memory (SRAM) architectures. More particularly, it pertains to power-efficient SRAM designs with selective memory bank activation capabilities for use in system-on-chip (SoC) applications.

### BACKGROUND

System-on-Chip (SoC) designs frequently incorporate multiple instances of Static Random Access Memory (SRAM) circuits. These SRAM circuits typically include components such as decoders, control circuitry, and input/output (I/O) circuitry. In conventional designs, it is common to find SRAM memory circuits of varying sizes within a single SoC, such as 16-bit, 32-bit, and 64-bit configurations.

Part of the rationale behind implementing different sizes of SRAM circuits stems from power consumption considerations. Larger memory arrays, particularly those with more columns, consume more power during read and write operations. Consequently, it may be advantageous to perform certain operations exclusively on smaller-sized memories to optimize power efficiency.

However, this conventional approach presents several challenges. The need to connect multiple conductive lines to different SRAM memory circuits consumes significant chip area. This increased routing complexity can lead to layout inefficiencies and potential signal integrity issues. Additionally, each SRAM memory circuit typically requires its own decoder, control circuitry, and I/O components. This redundancy in hardware resources prevents the obtainment of potential power savings that could be achieved through shared circuitry.

These limitations in conventional SRAM implementations within SoCs highlight the need for further development in memory architecture design. Developments that address the issues of routing complexity, circuit redundancy, area efficiency, and power optimization are required.

### SUMMARY

In an embodiment, a static random-access memory (SRAM) device with enhanced flexibility and power efficiency comprises two memory cores with different bit widths and a control section that receives a partial word signal. This signal allows independent control of each memory core, enabling or disabling them selectively. The SRAM device further includes a decoder circuit and multiple word line drivers, which can be independently enabled or disabled for each memory core based on the partial word signal. The word line drivers are organized into two sets, each coupled to the word lines of a respective memory core. Power control circuits selectively provide power to each set of drivers according to the partial word signal. This architecture allows for more granular control over memory access and power consumption, potentially improving the device's overall efficiency and performance in applications requiring variable memory access patterns.

### BRIEF DESCRIPTION OF THE DRAWINGS

FIG. 1A is a block diagram of a static random-access memory (SRAM) with equal-width memory banks and a half-word selection mechanism.

FIG. 1B is a block diagram of an innovative static random-access memory (SRAM) with uneven memory banks and a partial word selection mechanism.

FIG. 2 is a schematic diagram illustrating the decoder circuitry and word line drivers for the SRAM of FIG. 1B.

FIG. 3 is a schematic diagram showing a portion of the control section responsible for generating certain control signals for the SRAM.

FIG. 4 is a schematic diagram showing the detailed structure of memory cores and their associated bitline control circuitry.

FIG. 5A is a graph showing the power consumption of the full SRAM design of FIG. 1A.

FIG. 5B is a graph showing the power consumption of the SRAM design of FIG. 1A operating in half-word mode.

FIG. 6A is a graph showing the power consumption of the full SRAM design of FIG. 1B.

FIG. 6B is a graph showing the power consumption of the SRAM design of FIG. 1B operating in partial-word mode.

### DETAILED DESCRIPTION

The following disclosure enables a person skilled in the art to make and use the subject matter described herein. The general principles outlined in this disclosure can be applied to embodiments and applications other than those detailed above without departing from the spirit and scope of this disclosure. It is not intended to limit this disclosure to the embodiments shown, but to accord it the widest scope consistent with the principles and features disclosed or suggested herein.

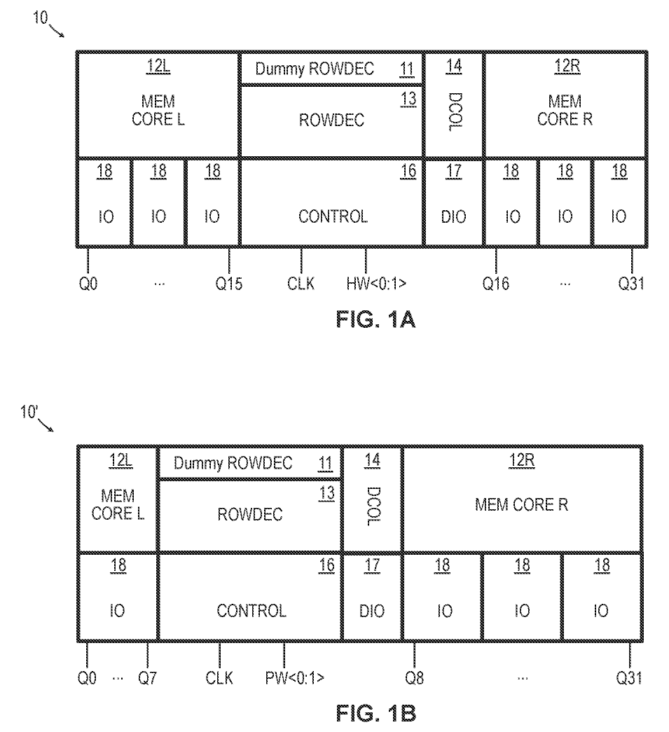

A block diagram for a static random-access memory (SRAM) 10 for use within a system-on-a-chip (SOC) is shown in FIG. 1A. This SRAM 10 is designed to allow for selective activation of memory banks, resulting in improved power efficiency. The SRAM 10 includes two memory banks: a left memory core (MEM CORE L) 12L and a right memory core (MEMCORE R) 12R, each 16 bits wide, for a total memory width of 32 bits.

A row decoder (ROWDEC) 13 selects specific rows within both memory cores 12L, 12R based on provided address inputs. Input/output (IO) blocks 18 facilitate data transfer to and from the memory cores 12L, 12R. The SRAM 10 includes a total of 32 data pins, labeled Q0 through Q31. Pins Q0 to Q15 serve the left bank (memory core 12L), while pins Q16 to Q31 serve the right bank (memory core 12R). A dummy column (DCOL) 14 aids in accounting for process variations and therefore maintaining consistent and stable performance during read and write operations performed on the memory cores 12L, 12R. A dummy row decoder 11 performs an analogous function to the row decoder 13, but for the dummy column 14 rather than the left memory core 12L and right memory core 12R.

A control circuit 16 receives and manages various signals, including address inputs and functional commands (e.g., write enable, chip select), coordinating the activities of the various components. This SRAM implements a half-word selection mechanism, controlled by the HW<0:1> signal. This allows the circuit to selectively activate either the left bank 12L, the right bank 12R, or both banks simultaneously, achieving power savings by driving only the necessary bank(s) for a given operation.

The half-word mechanism functions as follows: when the signal HW<0:1> is set to select only the left bank, the SRAM activates only memory core 12L and its associated circuitry, leaving the memory core 12R inactive. Similarly, when set to select only the memory core 12R, it activates memory core 12R while leaving the memory core 12L inactive. When both banks are selected, the SRAM operates as a full 32-bit memory. This selective activation results in significant power savings during operations that do not require the full memory bit-width.

This design offers advantages in power efficiency through selective bank activation. However, the SRAM 10 design architecture requires that the left memory core 12L and the right memory core 12R be of equal bit width. This requirement is inherent to the functionality of the half-word mechanism functionality, as it assumes symmetrical banks for proper operation. The need for equal-width banks ensures that when either bank is selected individually, it can handle the same data width, maintaining consistency in memory operations regardless of which bank is active. Thus, this SRAM 10 design does not permit the use of asymmetric banks, such as an 8-bit wide bank and a 24-bit wide bank, which limits its flexibility in certain applications where variable memory widths might be desirable.

FIG. 1B illustrates a block diagram for an innovative static random-access memory (SRAM) 10' designed to allow for uneven-width memory banks, addressing the limitations of the design shown in FIG. 1A. Unlike the design shown in FIG. 1A, these memory cores (MEMCORE) 12L, 12R can have different bit widths. In this example, the left memory core 12L is 8 bits wide, while the right memory core 12R is 24 bits wide, resulting in a total memory width of 32 bits. Here, pins Q0 to Q7 serve the left bank (memory core 12L), while pins Q8 to Q31 serve the right bank (memory core 12R), reflecting the asymmetric nature of the memory banks.

The SRAM 10' implements a Partial Word Feature, which provides independent control of the left and right memory banks. This feature is managed through the PW<0:1> signal, a two-bit signal received at two pins: PW<0> and PW<1>. These pins allow for dynamic and static power savings by selectively enabling or disabling either memory bank 12L, 12R. The control section 16 receives the PW<0> and PW<1> signals, interpreting these inputs to manage the activation of the memory cores accordingly.

The functionality of the PW<0:1> signal operates as follows: When both PW<1> and PW<0> are 0, both left memory core 12L and right memory core 12R are enabled, allowing full access to the entire 32-bit memory width. If PW<1> is 0 and PW<0> is 1, memory core 12L is disabled while memory core 12R remains enabled, providing access only to the memory core 12R (24 bits in this example) and reducing power consumption by disabling memory core 12L. Conversely, when PW<1> is 1 and PW<0> is 0, memory core 12L is enabled while memory core 12R is disabled, offering access only to the memory core 12L (8 bits in this example) and achieving power savings by disabling the larger memory core 12R. Finally, if both PW<1> and PW<0> are 1, both memory cores 12L, 12R are disabled, a state that may be used when the entire SRAM is to be powered down while maintaining overall chip operation.

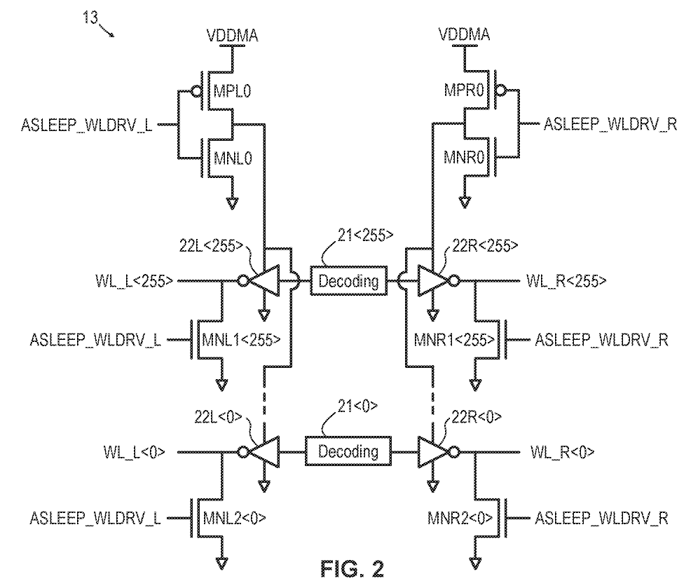

FIG. 2 illustrates the decoder circuitry and word line drivers 13 that generate the word line signals for the SRAM 10'.

The circuit includes PMOS transistor MPL0, which has its source connected to VDDMA and its drain connected to the drain of NMOS transistor MNL0. VDDMA represents the memory array supply voltage, while VDDMP represents the memory periphery supply voltage. RTAM (Retention Test Array Mode) signals control the retention mode operation of the memory cores.

Transistor MNL0 has its source connected to ground. Both transistors MPL0 and MNL0 have their gates coupled to receive the ASLEEP_WLDRV_L signal.

Similarly, PMOS transistor MPR0 has its source connected to VDDMA and its drain connected to the drain of NMOS transistor MNR0. Transistor MNR0 has its source connected to ground. Both transistors MPR0 and MNR0 have their gates coupled to receive the ASLEEP_WLDRV_R signal.

The circuit contains 256 decoding circuits, labeled 21<0> to 21<255>. Each decoding circuit 21 receives address inputs and generates decoded signals for both the left and right memory cores. The outputs of each decoding circuit 21 are connected to a pair of inverters: inverter 22L for the left memory core 12L and inverter 22R for the right memory core 12R. There are 256 inverters 22L, labeled 22L<0> to 22L<255>, and 256 inverters 22R, labeled 22R<0> to 22R<255>.

Each inverter 22L is powered between the voltage at the common drains of transistors MPL0/MNL0 and ground. The output of each inverter 22L drives a word line WL_L<x> for the left memory core 12L, where x ranges from 0 to 255.

Similarly, each inverter 22R is powered between the voltage at the common drains of transistors MPR0/MNR0 and ground. The output of each inverter 22R drives a word line WL_R<x> for the right memory core 12R, where x ranges from 0 to 255.

NMOS transistors MNL1<0> to MNL1<255> have their drains connected to the outputs of inverters 22L<0> to 22L<255> respectively, and their sources connected to ground. Their gates are controlled by the ASLEEP_WLDRV_L signal.

NMOS transistors MNR1<0> to MNR1<255> have their drains connected to the outputs of inverters 22R<0> to 22R<255> respectively, and their sources connected to ground. Their gates are controlled by the ASLEEP_WLDRV_R signal.

The operation of this circuit is as follows: When ASLEEP_WLDRV_L is asserted (high) to disable the memory core 12L, transistor MPL0 is turned off and transistor MNL0 is turned on, effectively grounding the power supply of all inverters 22L. This disables the word line drivers for the left memory core 12L. Simultaneously, transistors MNL1<0> to MNL1<255> turn on, ensuring that all word lines WL_L<x> are pulled to ground, preventing any accidental activation of memory cells in the left core.

Conversely, when ASLEEP_WLDRV_L is deasserted (low) to enable the memory core 12L, transistor MPL0 is turned on and transistor MNL0 is turned off, connecting the inverters 22L to VDDMA. This enables the inverters 22L to drive the word lines WL_L<x> based on the output of the decoding circuits 21. In this state, transistors MNL1<0> to MNL1<255> are turned off, allowing the word lines to be driven high or low as needed.

The same principle applies to ASLEEP_WLDRV_R and its control over transistors MPR0, MNR0, inverters 22R, and transistors MNR1<0> to MNR1<255> for activating or deactivating the right memory core 12R.

This design allows for independent control of the word lines for each memory core, enabling the partial word functionality and power-saving capabilities of the SRAM 10'. By selectively asserting or deasserting ASLEEP_WLDRV_L and ASLEEP_WLDRV_R, the circuit can activate or deactivate each memory core independently, supporting the partial word operations described earlier.

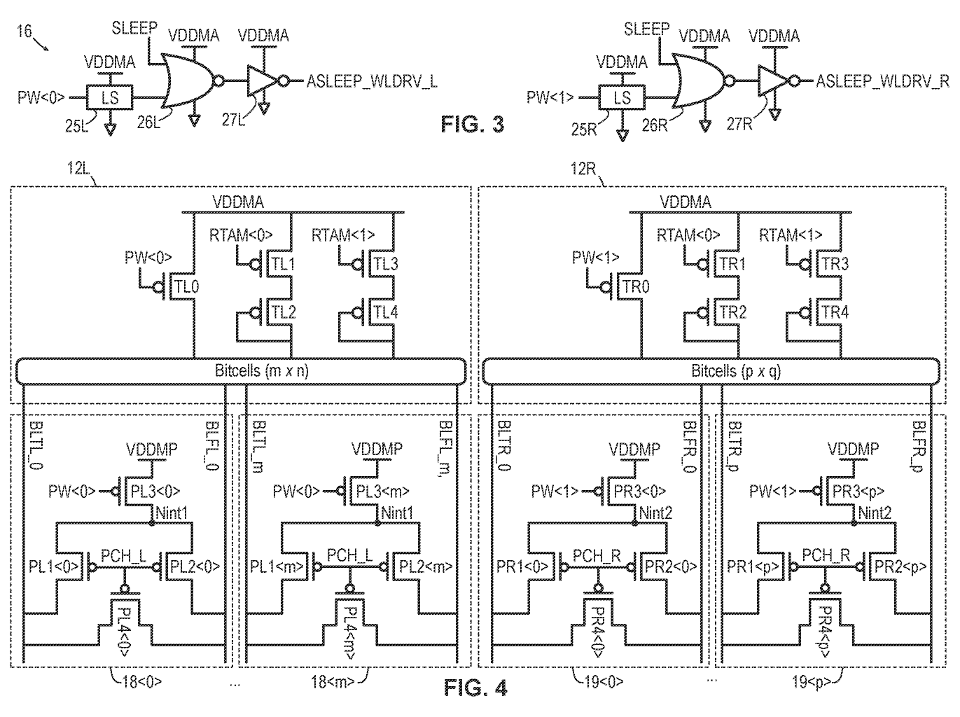

FIG. 3 illustrates a portion of the control section 16 responsible for generating the ASLEEP_WLDRV_L and ASLEEP_WLDRV_R signals. This circuitry controls the activation and deactivation of word line drivers for the left and right memory cores of the SRAM 10'.

The circuit generates the ASLEEP_WLDRV_L signal includes a level shifter (LS) 25L that receives the PW<0> signal as input. This level shifter converts the PW<0> signal from its original voltage level to the VDDMA level, ensuring compatibility with the memory array supply voltage. The output of the level shifter 25L feeds into a first input of a NOR gate 26L, which also receives the SLEEP signal as its second input. The resulting output from the NOR gate 26L then passes through an inverter 27L to produce the final ASLEEP_WLDRV_L signal.

The circuit that generates the ASLEEP_WLDRV_R mirrors this structure. Included is a level shifter 25R that receives and converts the PW<1> signal to the VDDMA level. The shifted signal then enters a NOR gate 26R at a first input, which also takes the SLEEP signal as its second input. An inverter 27R processes the output of the NOR gate 26R to generate the ASLEEP_WLDRV_R signal.

When the SLEEP signal is asserted (high), both NOR gates 26L and 29R output a low signal regardless of the PW inputs. Consequently, both ASLEEP_WLDRV_L and ASLEEP_WLDRV_R are asserted (high) after passing through their respective inverters, effectively disabling both memory cores. This feature enables a low-power sleep mode for the entire SRAM.

When the SLEEP signal is deasserted (low), the circuit responds to the individual PW signals. If PW<0> is low, ASLEEP_WLDRV_L will be deasserted (low), enabling the left memory core 12L. Conversely, if PW<0> is high, ASLEEP_WLDRV_L will be asserted (high), disabling the left memory core. The same principle applies to PW<1> and its control over ASLEEP_WLDRV_R for the right memory core 12R.

FIG. 4 illustrates the detailed structure of memory cores 12L and 12R, along with their associated bitline control circuitry.

In memory core 12L, PMOS transistor TL0 has its source connected to VDDMA and its gate controlled by PW<0>. The drain of transistor TL0 is connected directly to the m x n bitcell array of memory core 12L. PMOS transistors TL1 and TL2 are connected in series. The source of transistor TL1 is connected to VDDMA, and its gate is controlled by RTAM<0>. The drain of transistor TL1 is connected to the source of transistor TL2. The gate and drain of transistor TL2 are connected together (diode-connected configuration), which is also connected to the bitcell array. Similarly, PMOS transistors TL3 and TL4 are also connected in series. The source of transistor TL3 is connected to VDDMA, and its gate is controlled by RTAM<1>. The drain of transistor TL3 is connected to the source of transistor TL4. The gate of transistor TL4 is connected to the drain of transistor TL4, which is also connected to the bitcell array. Collectively, transistors TL0-TL4 provide a virtual supply voltage to the bitcells of memory core 12L.

In memory core 12R, a similar structure is implemented. PMOS transistor TR0 has its source connected to VDDMA and its gate controlled by PW<1>. The drain of transistor TR0 is connected directly to the p x q bitcell array of memory core 12R. PMOS transistors TR1 and TR2 are connected in series, with the source of transistor TR1 connected to VDDMA and the gate of transistor TR1 being controlled by RTAM<0>. The source of transistor TR2 is connected to the drain of transistor TR1, and the gate of transistor TR2 is connected to the drain of transistor TR2, which connects to the bitcell array. Similarly, PMOS transistors TR3 and TR4 form another series connection, with the source of transistor TR3 connected to VDDMA and the gate of transistor TR3 being controlled by RTAM<1>. The source of transistor TR4 connects to the drain of transistor TR3, and the gate and drain of transistor TR4 are connected to one another as well as to the bitcell array. As with the left core, transistors TR0-TR4 provide a virtual supply voltage to the bitcells of memory core 12R.

The operation of the virtual supply voltage circuit in each memory core 12L and 12R is as follows.

In a normal operating mode, PW is low, while RTAM<0> and RTAM<1> are high. In this normal operating mode, when PW (PW<0> for 12L, PW<1> for 12R) is low, transistor TL0/TR0 is turned on, providing a direct connection from VDDMA to the bitcell array. This provides full voltage and current supply during normal read and write operations. In this mode, transistors TL1-TL4 (or transistors TR1-TR4) are off and do not affect the supply voltage.

In a power-down mode (PW is high), transistor TL0/TR0 is turned off, disconnecting the direct VDDMA supply from the corresponding bitcell array. This reduces power consumption by cutting off the main supply path. The memory contents are not necessarily retained in this state unless the RTAM signals are activated; if they are not, a complete power-down of the memory is performed. In retention mode, where PW is high and either RTAM<0> or RTAM<1> (or both) are low, it activates one or both of the series-connected transistor pairs (transistors TL1-TL2 and transistors TL3-TL4, or transistors TR1-TR2 and transistors TR3-TR4). These series-connected transistors act as a high-resistance path between VDDMA and the bitcell array. The diode-connected configuration of transistors TL2/TL4 (or transistors TR2/TR4) provides for a voltage drop, supplying a lower voltage to the bitcell array – just enough to retain data but not enough for normal read/write operations.

By having two separate RTAM signals (RTAM<0> and RTAM<1>), fine-grained control over the retention mode may be obtained. This could be used to provide different levels of retention current or for redundancy.

Below each bitcell array, the circuit includes bitline control circuitry, labeled 18<0> to 18<m> for the memory core 12L, and labeled 19<0> to 19<p> for the memory core 12R. For memory core 12L, this circuitry is replicated m+1 times (from 0 to m), shown as 18<0>, …, 18<m>, while for memory core 12R, it is replicated p+1 times (from 0 to p), shown as 19<0>, …, 19<p>.

In the bitline control circuitry 18<0> to 18<m> for memory core 12L, PMOS transistors PL3<0> to PL3<m> have their sources connected to VDDMP and their gates controlled by PW<0>. The drains of transistors PL3<0> to PL3<m> are connected to a node labeled Nint1. PMOS transistors PL1<0> to PL1<m> and PL2<0> to PL2<m> have their sources connected to node Nint1, with the drains of transistors PL1<0> to PL1<m> being connected to bit lines BLTL_0 to BLTL_m and the drains of transistors PL2<0> to PL2<m> being connected to complementary bit lines BLFL_0 to BLFLm. The gates of transistors PL1<0> to PL1<m> and transistors PL2<0> to PL2<m> are controlled by precharge signal PCH_L. PMOS transistors PL4<0> to PL4<m> are connected between bit lines BLTL_0 to BLTL_m and BLFL_0 to BLFL_m.

The bitline control circuitry for memory core 12R follows the same pattern. In the bitline control circuitry 19<0> to 19<p>, PMOS transistors PR3<0> to PR3<p> have their sources connected to VDDMP and their gates controlled by PW<1>. The drains of transistors PR3<0> to PR3<p> are connected to a node labeled Nint2. PMOS transistors PR1<0> to PR1<p> and PR2<0> to PR2<p> have their sources connected to node Nint2, with the drains of transistors PR1<0> to PR1<p> being connected to bit lines BLTR_0 to BLTR_p and the drains of transistors PR2<0> to PR2<p> being connected to complementary bit lines BLFR_0 to BLFR_p. The gates of transistors PR1<0> to PR1<p> and transistors PR2<0> to PR2<p> are controlled by precharge signal PCH_R. PMOS transistors PR4<0> to PR4<p> are connected between bit lines BLTR_0 to BLTR_p and BLFR_0 to BLFR_p.

This bitline control circuitry allows for individual control of bitline precharging and access for each memory core, supporting the partial word functionality of the SRAM. The PW<0> and PW<1> signals control the activation of the bitline precharge circuitry for the left and right memory cores respectively, enabling power savings when a particular core is not in use.

The precharge signals PCH_L and PCH_R control the equalization of the bitlines before read or write operations. When asserted, these signals turn on the corresponding PL1, PL2, PR1, and PR2 transistors, connecting the bitlines to the precharge voltage at nodes Nint1 and Nint2.

The transistors PL4 and PR4 serve as equalizing transistors, ensuring that the true and complementary bitlines (BLTL and BLFL for the left core, BLTR and BLFR for the right core) are at the same potential before an operation begins.

The asymmetric design of the memory cores (m x n for 12L and p x q for 12R) is reflected in the differing number of bitline control circuits for each core, allowing for flexible memory configurations while maintaining individual core control. This design enables the SRAM to support partial word operations efficiently, activating only the necessary portions of the memory array and associated control circuitry based on the current operation requirements.

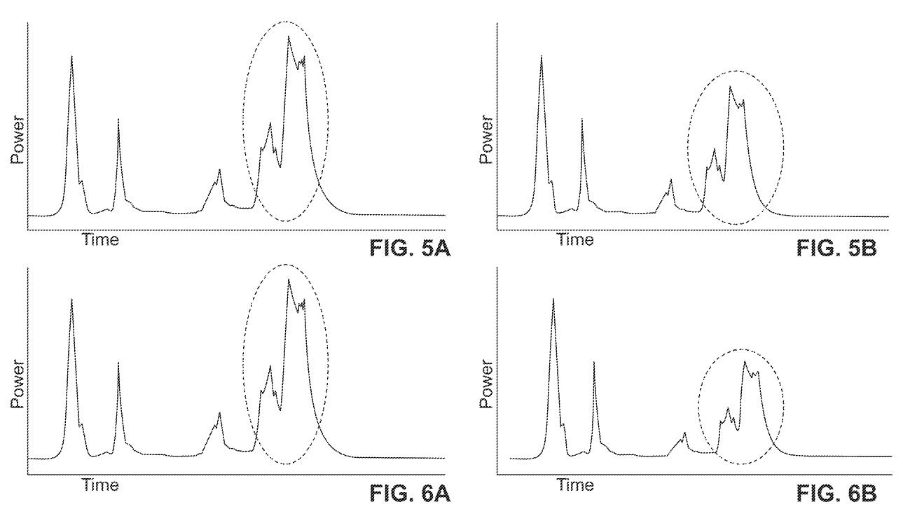

FIG. 5A depicts the power consumption profile of the full SRAM design shown in FIG. 1A. The graph shows several peaks of varying heights, representing different levels of power consumption during various operations. A dotted oval highlights a region of particular interest, where a cluster of high power consumption peaks can be observed. These peaks correspond to periods of full memory access, where both the left and right memory banks are active simultaneously.

FIG. 5B illustrates the power consumption of the same SRAM design (FIG. 1A) operating in half-word mode. In this mode, only one of the two equal-width memory banks is active at a time. The graph shows a similar overall pattern to FIG. 5A, but with a notable difference in the highlighted region. The power consumption peaks within the dotted oval appear lower in amplitude compared to FIG. 5A, indicating reduced power consumption. This reduction is consistent with the expected behavior of the half-word mode, where only half of the memory is active at any given time.

FIG. 6A shows the power consumption profile of the full SRAM design shown in FIG. 1B. The graph exhibits a pattern similar to FIG. 5A, with multiple power consumption peaks of varying heights. The highlighted region enclosed by the dotted oval shows a cluster of high peaks, representing periods of full memory access where both the 8-bit and 24-bit memory banks are active.

FIG. 6B depicts the power consumption of the SRAM design from FIG. 1B operating in partial-word mode. This mode allows for selective activation of either the 8-bit bank, the 24-bit bank, or both. The graph shows a marked difference in the highlighted region compared to FIG. 6A. The power consumption peaks within the dotted oval are significantly reduced in amplitude, indicating substantial power savings. This reduction is more pronounced than in FIG. 5B, due to the flexibility offered by the partial-word feature in the asymmetric design, allowing for more granular control over memory bank activation in terms of selection of the size of memory bank activated.

The partial word functionality offers several advantages, including dynamic power savings by allowing selective activation of memory banks based on immediate system needs, static power savings in scenarios where only a portion of the memory is needed for extended periods, flexibility in efficiently using the asymmetric memory design for various operational modes within the SOC, and granular control through the two-bit PW signal for precise management of active memory portions. Thus, the asymmetric SRAM design described herein gains enhanced efficiency and versatility, adapting to different operational requirements within the SOC while minimizing power usage.

It is evident that modifications and variations can be made to what has been described and illustrated herein without departing from the scope of this disclosure.

Although this disclosure has been described with a limited number of embodiments, those skilled in the art, having the benefit of this disclosure, can envision other embodiments that do not deviate from the disclosed scope. Furthermore, skilled persons can envision embodiments that represent various combinations of the embodiments disclosed herein made in various ways.

1. A static random-access memory (SRAM) device, comprising:
a first memory core having a first bit width;
a second memory core having a second bit width different from the first bit width;
a control section configured to receive a partial word signal, and to selectively enable or disable each of the first memory core and the second memory core based on the partial word signal, thereby allowing independent control of the first and second memory cores.

2. The SRAM device of claim 1, further comprising:
a decoder circuit coupled to the first and second memory cores; and
a plurality of word line drivers coupled to the decoder circuit, wherein the word line drivers are configured to be selectively enabled or disabled for each of the first and second memory cores based on the partial word signal;
wherein the word line drivers comprise:
a first set of drivers coupled to word lines of the first memory core;
a second set of drivers coupled to word lines of the second memory core;
a first power control circuit configured to selectively provide power to the first set of drivers based on the partial word signal; and
a second power control circuit configured to selectively provide power to the second set of drivers based on the partial word signal.

3. The SRAM device of claim 1, wherein the control section comprises:
a first level shifter configured to receive a first bit of the partial word signal;
a second level shifter configured to receive a second bit of the partial word signal;
a first logic circuit coupled to the output of the first level shifter and configured to generate a first sleep signal for the first memory core; and
a second logic circuit coupled to the output of the second level shifter and configured to generate a second sleep signal for the second memory core.

4. The SRAM device of claim 3, wherein the first logic circuit comprises a NOR gate and an inverter, and wherein the second logic circuit comprises a NOR gate and an inverter.

5. The SRAM device of claim 1, further comprising:
a first virtual supply voltage circuit coupled to the first memory core; and
a second virtual supply voltage circuit coupled to the second memory core;
wherein each of the first and second virtual supply voltage circuits is configured to selectively provide one of a full operating voltage and a data retention voltage to its respective memory core based on the partial word signal.

6. The SRAM device of claim 5, wherein each of the first and second virtual supply voltage circuits comprises:
a first transistor coupled between a supply voltage and the respective memory core, the first transistor controlled by the partial word signal;
a first pair of series-connected transistors coupled between the supply voltage and the respective memory core; and
a second pair of series-connected transistors coupled between the supply voltage and the respective memory core;
wherein the first and second pairs of series-connected transistors are controlled by retention mode signals.

7. The SRAM device of claim 1, further comprising:
a first set of bitline control circuits coupled to the first memory core; and
a second set of bitline control circuits coupled to the second memory core;
wherein each set of bitline control circuits is configured to be selectively enabled or disabled based on the partial word signal.

8. The SRAM device of claim 1, wherein the partial word signal comprises at least two bits.

9. A method of operating a static random-access memory (SRAM) device, the method comprising:
receiving a partial word signal; and
selectively enabling or disabling each of a first memory core and a second memory core based on the partial word signal, thereby allowing independent control of the first and second memory cores;
wherein the first memory core has a first bit width and the second memory core has a second bit width different from the first bit width.

10. The method of claim 9,
further comprising:
selectively enabling or disabling a first set of word line drivers coupled to the first memory core based on the partial word signal; and
selectively enabling or disabling a second set of word line drivers coupled to the second memory core based on the partial word signal;
wherein:
selectively enabling or disabling the first set of word line drivers comprises controlling a first power control circuit to selectively provide power to a first set of inverters coupled to word lines of the first memory core; and
selectively enabling or disabling the second set of word line drivers comprises controlling a second power control circuit to selectively provide power to a second set of inverters coupled to word lines of the second memory core.

11. The method of claim 9, further comprising:
level shifting a first bit of the partial word signal;
level shifting a second bit of the partial word signal;
generating a first sleep signal for the first memory core based on the level-shifted first bit; and
generating a second sleep signal for the second memory core based on the level-shifted second bit.

12. The method of claim 9, wherein:
generating the first sleep signal comprises performing a NOR operation followed by an inversion operation on the level-shifted first bit and a sleep signal; and
generating the second sleep signal comprises performing a NOR operation followed by an inversion operation on the level-shifted second bit and the sleep signal.

13. The method of claim 9, further comprising:
selectively providing one of a full operating voltage and a data retention voltage to the first memory core based on the partial word signal; and
selectively providing one of a full operating voltage and a data retention voltage to the second memory core based on the partial word signal.

14. The method of claim 9, further comprising:
selectively enabling or disabling a first set of bitline control circuits coupled to the first memory core based on the partial word signal; and
selectively enabling or disabling a second set of bitline control circuits coupled to the second memory core based on the partial word signal.

15. The method of claim 9, further comprising:
operating the SRAM device in a full-power mode by enabling both the first and second memory cores;
operating the SRAM device in a first partial-power mode by enabling the first memory core and disabling the second memory core;
operating the SRAM device in a second partial-power mode by enabling the second memory core and disabling the first memory core; and
operating the SRAM device in a low-power mode by disabling both the first and second memory cores.
